(19) United States
(12) Patent Application Publication
(10) Pub. No.: US 2007/0202811 A1
(43) Pub. Date: Aug. 30, 2007

(54) SYSTEM FOR DETERMINING AND DISPLAYING COVERAGE REGIONSOF AN RFID READER/INTEGRATOR

(76) Inventor: Benson Chanowitz, Brooklyn, NY (US)

Correspondence Address: GOTTLIEB RACKMAN & REISMAN PC, 270 MADISON AVENUE, 8TH FLOOR, NEW YORK, NY, 100160601, US

(21) Appl. No.: 11/619,876

(22) Filed: Jan. 4, 2007

Related U.S. Application Data
(60) Provisional application No. 60/757,791, filed on Jan. 9, 2006.

(51) Int. Cl. H04B 17/00; H04Q 7/20; G08B 13/14; G01R 13/00

(52) U.S. Cl. 455/67.12; 340/572.7; 455/424; 702/66

(57) ABSTRACT

A 3-D verification system determines the volume effectively covered by a reader/integrator of RFID tags. This system is useful for displaying the distortions and the holes in an RF coverage region that exist within its volume. It also determines and displays how the coverage region changes as a function of the power supplied to the reader/integrator. An RFID reader/integrator is mounted in an anechoic chamber facing an array of RFID tags in close proximity to each other. Each RFID tag's position within the grid is prerecorded in a computer database. The tag arrangement and location is also displayed by a 3-D visualization program. Different tag arrangement configurations comprise different embodiments of the invention. Each is designed to provide coverage of the volume in a layered, preferably geometrically regular configuration.

This invention claims priority of U.S. Provisional Application 60/757,791 filed Jan. 9, 2006.

### FIELD OF THE INVENTION

This invention pertains to the technology of radio frequency identification devices (RFID) and to determining and displaying RF field configurations in a volume where RFIDs are active.

### BACKGROUND OF THE INVENTION

RFID technology allows for the easy handling of items without direct sight of the tagged object. By setting up a portal through which the objects pass, a reading event can take place in a reader/integrator and the event recorded. The technology allows each item to be individually tracked as an independent entity allowing for better control over a plurality of objects. The hardware consists of an RFID tag that is attached to an item or is embedded in it. A reader/integrator that records the presence of the tagged object may also add information to the tag depending on the sophistication of the tag. Each reader/integrator has an antenna as one of its components. In an ideal configuration this antenna propagates a signal with vertical or horizontal polarization having an asymmetrical prolate ellipsoidal field of coverage, i.e. one that resembles in shape an air blimp. Any tags that come into the field of this signal can be stimulated to emit RF signals back to the antenna or other receiver and thereby be identified. The RFID tag des not require its own internal power supply. The reader signal powers up the RFID tag and gives it enough energy output to let the reader obtain its identity. In reality the antenna plume is distorted, and there are holes in the plume field. This causes the reader to not have a good read rate and makes it necessary to locate more readers in a read zone to achieve a 100% read rate, which is what is normally desired. An RFID reader antenna requires testing to locate no-read regions before deployment and implementation. Proper procedure for implementation requires a method involving both an antenna patterning test and a reader performance test for location and accuracy.

In theory, an RFID reader antenna should have a known field of coverage. The field of coverage is determined by the power amplifiers supplying power to the antenna circuitry. The field pattern of radiation antennas is determined principally by the geometric configuration and orientation of the antennas and by the construction of the reception units. These antennas propagate a RF signal having a polarization plane typically oriented either vertically or horizontally. In a perfect world the polarization plane should completely fill an area having a perimeter with an oval shape (field). Any RFID tag present in this area may be assumed to be read, provided that the reader is preprogrammed to read that type of RFID tag. In reality there are holes in this oval field. An antenna patterning test is designed to locate those holes.

The current state of the art for locating the holes in a reader's antenna coverage pattern involves a process in which an individual makes marks on graph paper while another person holding an RFID tag moves it through the antenna field while monitoring where the reader detects the antenna signal. They move the tag in all directions, up and down and sideways and backwards and forwards, in order to get a clear picture of where the read occurred and where it did not. They carry out this procedure in an anechoic chamber so as not to have any interference with other radio or microwave frequencies.

### BRIEF DESCRIPTION OF THE INVENTION

The present invention is a system that enables visualization of the reader/integrator radiation pattern in order to adjust the reader/integrator to obtain an optimal reading angle and enhance and enlarge a “sweet spot” read area, in which a relatively strong signal is obtained.

To implement an embodiment of the invention, an anechoic chamber has placed within it multiple preferably identical RFID tags located throughout substantially its entire volume from floor to ceiling, across its width and along its length differing however in their individual identification codes, The volume should cover at least every location where an identification tag might appear with respect to the orientation of the antenna. A reader receives multiple signals from transducers incorporated into the RFID tags, each signal being capable of identifying the particular tag whose location is predetermined. An edgeware program is used to weed out multiple reads. When the reader is activated the identities of the individual RFID tags are read into a computer. This Information is relayed to the program and a 3-D image is created to view. This can then be recorded on any media for use in deploying the reader/integrator on line. As a convenience the manufacture's specs for the antenna are fed in to the computer along with the make and model of the reader.

### BRIEF DESCRIPTION OF THE DRAWINGS

FIG. 1 is a flow chart of the process steps of the invention.

FIG. 2 depicts an RFID generic tag.

FIG. 3 depicts the radiation plumes from RF antennas.

FIG. 4 depicts an RFID tag component enclosure.

FIG. 5 depicts the relative orientation of RFID tags mounted in an enclosure.

FIG. 6 depicts a stacked array of RFID component boxes.

FIG. 7 depicts several RFID component boxes stacked within an anechoic chamber.

FIG. 8 depicts a mounted reader and its radiation plume.

FIG. 9 depicts the reader of FIG. 8 at a higher power level.

FIG. 10 depicts a mounted reader with plume holes exhibited.

FIG. 11 depicts the reader of FIG. 10 at a higher power level.

FIG. 12 depicts a reader facing an array of RFID tag component boxes.

FIG. 13 depicts two mounted readers positioned to cancel each other no-read regions.

FIG. 14 depicts two mounted readers mounted to detect tags on an assembly line.

FIG. 15 depicts the basic anatomy of an RFID reader/integrator.

FIG. 16 depicts the anatomy of an RFID tag.

FIG. 17 depicts an RFID tag component box.

FIG. 18 depicts a fully deployed unit.

FIG. 19 depicts a folding hinge of the invention.

FIG. 20 depicts a unit in a folded position.

FIG. 21 depicts a stage in the folding of the invention.

FIG. 22 depicts half of a unit in a folded position.

FIG. 23 depicts an entire unit in a layout position.

FIG. 24 depicts a unit in folded position for transport.

FIG. 25 depicts the configuration of tags in an array.

### DETAILED DESCRIPTION OF PREFERRED EMBODIMENTS OF THE INVENTION

The present invention places multiple RFID tags preferably in an anechoic chamber from the ceiling to the floor, spaced close to one another compared to the potential size of holes in a radiation pattern and over substantially the volume of the chamber. By ceiling to floor is meant the upper and lower surfaces of a region throughout which reading of RFID tags is desired. The surfaces may be virtual or real. A reader is positioned so that it will face all the RFID tags. This enables the reader to detect signals from any RFID tag in its radiation field as well as to recognize the location of holes from which no response is received.

The RFID tag is read by the reader antenna. Each time there is a Read it is called an event. As the power to the antenna is increased the dimensions of the holes in the reader antenna pattern scale upwards along with the size of the plume, causing an increased area of non-coverage. The reader records every event and transfers this data to a computer edgeware program which displays the successful events. This software processes and defines all the reads. Where there are multiple reads of the same RFID tags the edgeware removes all the reads of a tag except for one read. The program then creates a list of all the RFID tags that were read. It subsequently transfers the data of the reads to a middleware program for further processing.

The software is preprogrammed with all the RFID tag identification numbers as well as the coordinates of their location in the anechoic chamber. This information is transferred to software program capable of creating a 3-D image, which draws a computer image of the configuration of the field. Once the image is prepared, it can be transferred to a printer to be printed or it can be stored on a disk or other media to be used for reader antenna positioning purpose.

Additionally this invention can be embodied in a portable device in which the RFID tags reside. In every reader antenna deployment at a read site, there is a sweet spot, which is the best place to read items as they pass through the reader's radiation field. This portable device can be used when field implementation is being done in order to detect sweet spots, holes, and electronic interferences. By using this portable device in the reading field, the number of reader antennas can be reduced, which effectively reduces excess radio frequency fields in the area while still maintaining a high read rate level. As more systems are deployed in the field, the added radio frequency waves will provide additional important uses for the present invention.

The RFID TAG of the present invention may be Class 0 tag=read only; Class 1 tag=read/write; or Class 1 (generation 2)=read/write. The invention can work equally well across the radio wave spectrum, can read/write many times and has a dense reading capacity. The invention may employ other or future classes of tags.

The RFID enclosure or box consists of RFID tags which are positioned vertically and horizontally in close proximity to each other. They are preferably as far apart as they are wide, meaning the distance of the tag from antenna to chip to antenna is the length between tags and the height will be the width of the tag. The distance between tags is determined by the type of tag deployed.

The general preferred structure is a 6′×6′×20″ box housing non overlapping, spatially separated RF tags. The tags are preferably arranged in columns 9 across, separated by 4 inches on all sides, with 4 layers of tags deep, also separated by 4 inches. Using this design, no tags will overlap yet the entire area of the assembly will be covered. The position and ID of these tags must be known to the software so that when the ID is generated by the reader, a corresponding location can be realized and recorded. A total of 364 tags will be needed for this purpose.

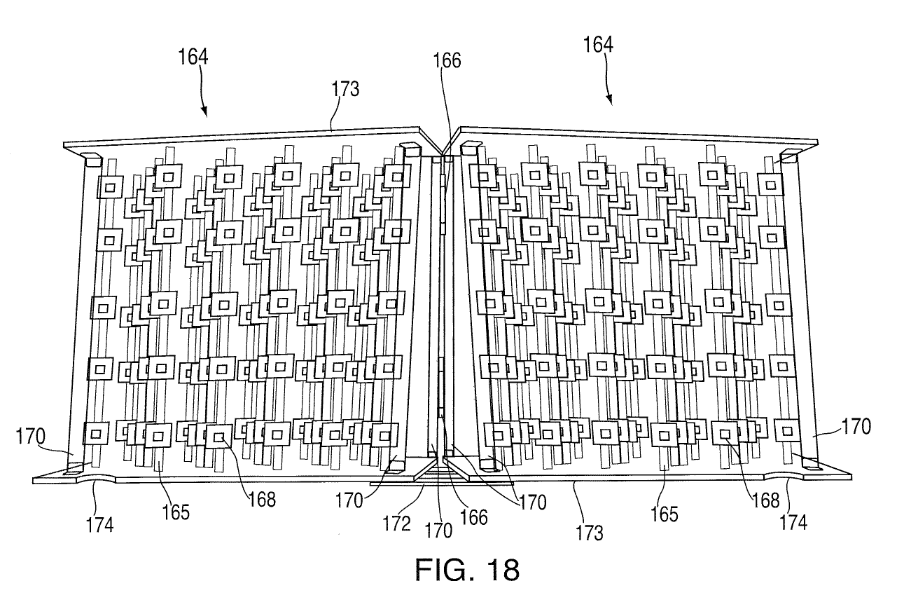

FIG. 18 depicts a view of the front of this design with numbers to indicate which tags belong to which layer of material. Again, these layers are separated by 4 inches, and all tags are separated by 4 inches to all sides. Referring to FIG. 18, the unit 164 is fully deployed. Hinges 166 and clasps and fasteners 172 keep unit 164 secure in a test mode position. Four poles 170 hold up each side of the unit. The top and bottom 173 have groove holes spaced to hold array columns 165 in equal distance from the next column. FRID friendly material is used in column 165 to hold RFID tags 168 in place. RFID friendly wheel attachment grooves 174 are shown at each corner position.

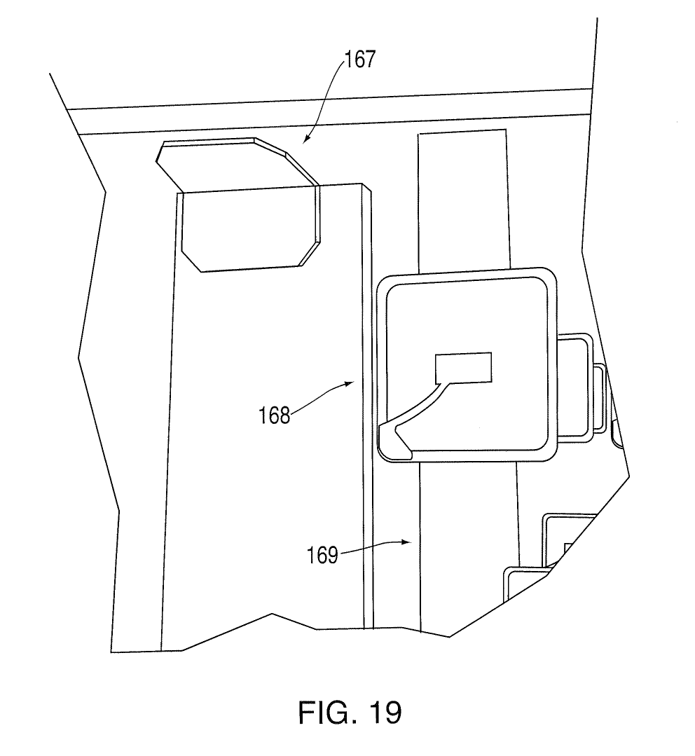

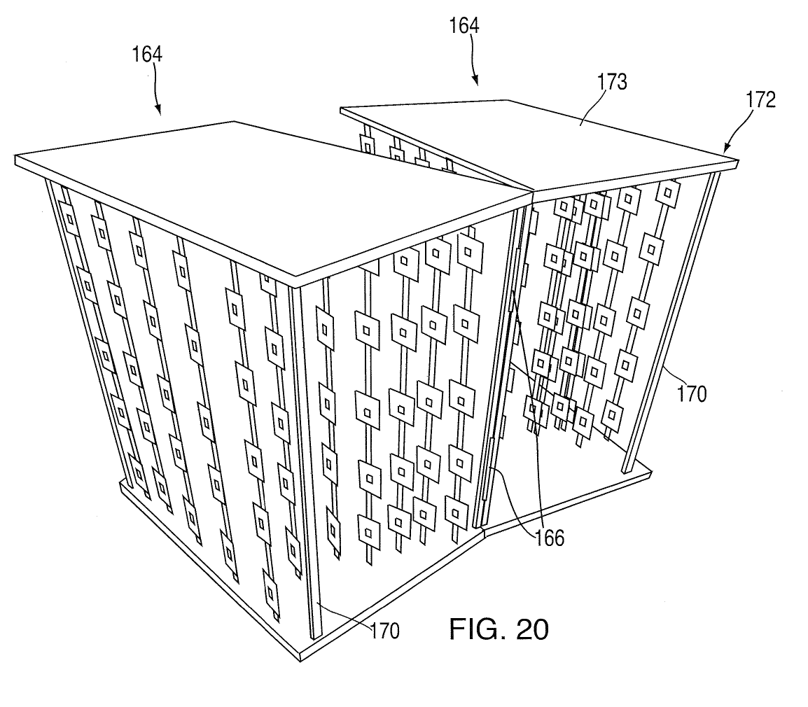

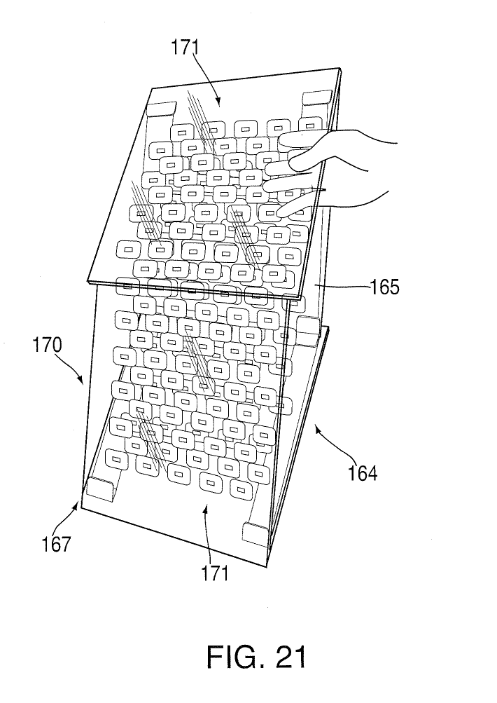

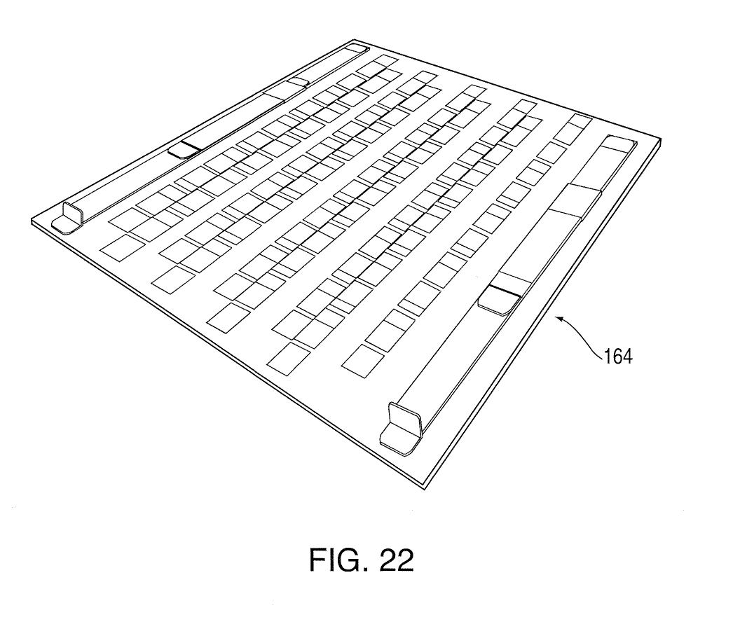

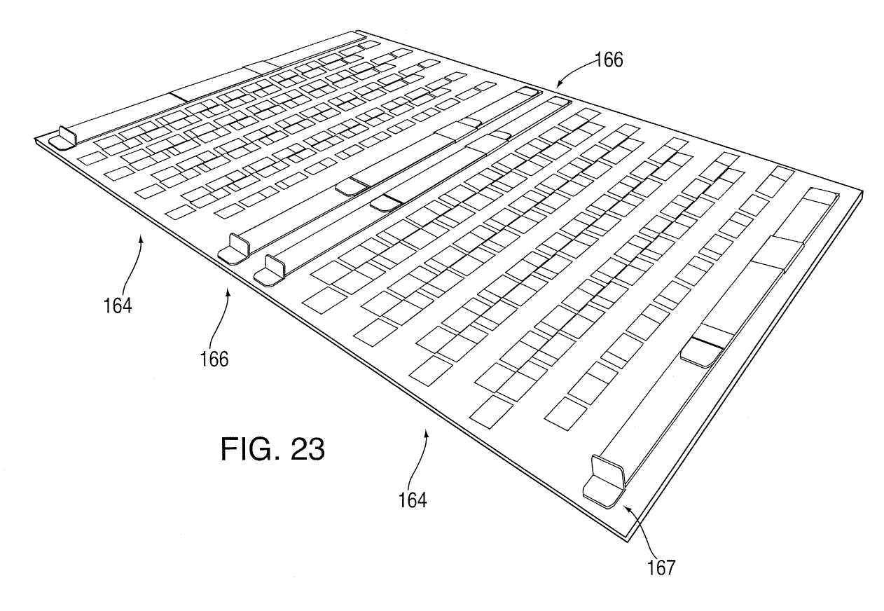

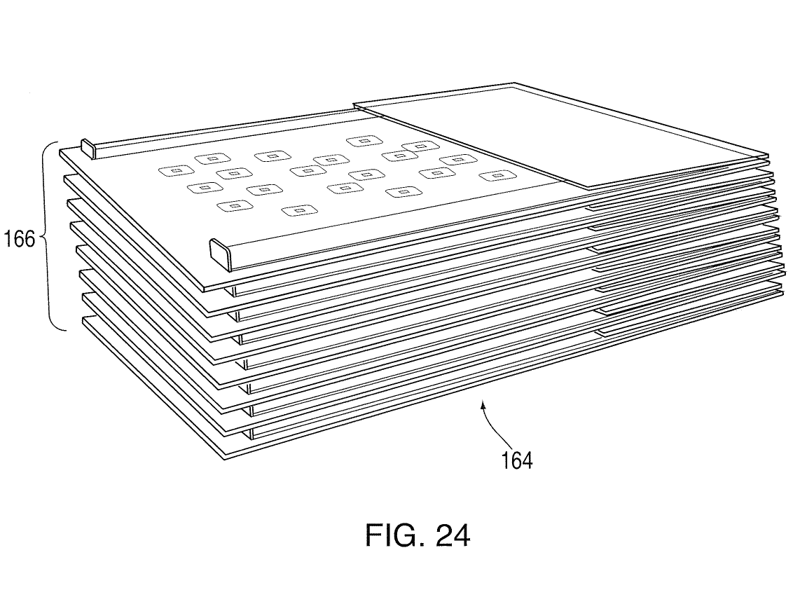

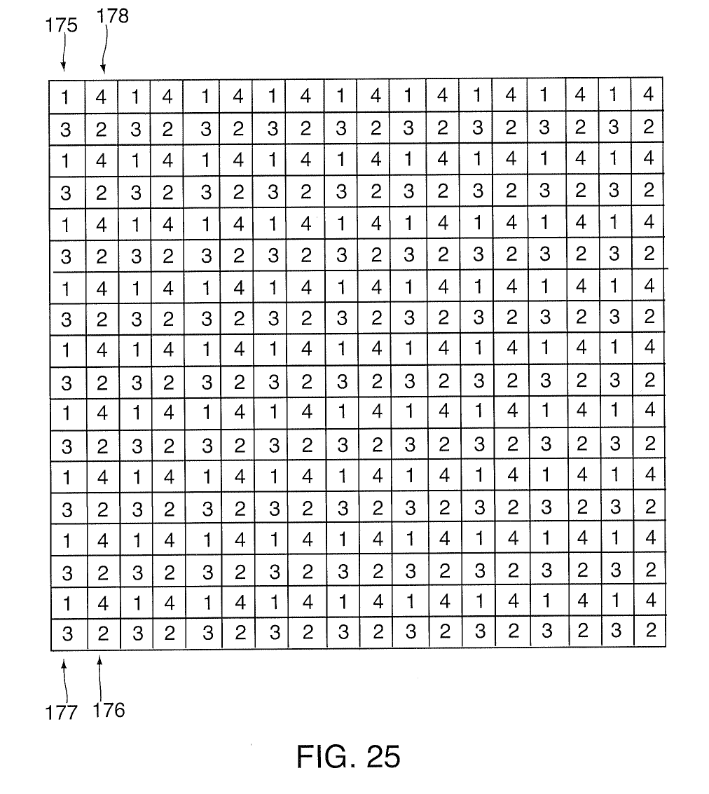

FIG. 19 is a close up look of the folding hinge 167 depicting RFID tag 168 and substrate 169 for spacing RFID tags. FIG. 20 shows unit 164 in a folded position with top and bottom 173 supported by columns 170 held together by hinges 166. FIG. 21 shows unit 164 in a folded position. Folding hinges 167 are shown in an upward mode for easy transport held together with column 170. The top and bottom of columns 165 are fastened together with Velcro 171 to allow for replacement of the columns if necessary. FIG. 22 shows half of a unit 164 in a folded position. FIG. 23 shows the entire unit 164 in a layout position. Hinges 166 and 167 are holding the unit in place. FIG. 24 shows unit 164 in a folded position ready to transport or deploy and stacked together with hinges 166. FIG. 25 shows configurations of a tag array as placed in rows separated from each other. Numbers 175 through 178 show rows 1,2,3 and 4.

Preferably, the unit will face an antenna, and the user will back away from the antenna until no tags read. Once this occurs, the software will prompt the user for the distance from the antenna. After entry, the software will prompt the user to move the assembly toward the antenna 1 foot, then after a timeout (for the user to step away) the reader will record the tags it sees. The software will again prompt a 1 foot movement and the process will repeat until the face of the antenna is reached. Bear in mind the tags are separated by 16 inches total from the first layer to the fourth, so the one foot interval provides for some overlap that is accounted for in the software. Alternatively, the unit may begin remote from the antenna and be advanced towards it.

Once the data is recorded, a three dimensional image will be generated showing the antennas primary lobe, and any imperfections in it. After running this test on all antennas in a zone, then inputting the height, distance across the zone, and angle, the images will be combined to show total zone coverage.

The assembly should center on the antenna throughout the test, however in the case of antennas near the floor this may not be possible, so the “absolute center” is able to be adjusted in the software to accommodate the possibility of a physical issue with obtaining true center.

The computer software will allow for filtration and data collection. This manages any type of reader for all manufacturers. The software also has the capacity to record the position of each RFID tag in the anechoic chamber.

A 3-D program will have stored the RFID tag component box coordinates. The boxes are stacked one on top of the other and next to each other to allow for a complete area to be saturated with tags. As the tags get read, the 3-D program allots a marker for each tag and a color is used to show where it is in the field. The tags that are not read are indicated by a different color and a final picture is allowed to emerge, illustrating what the area looks like.

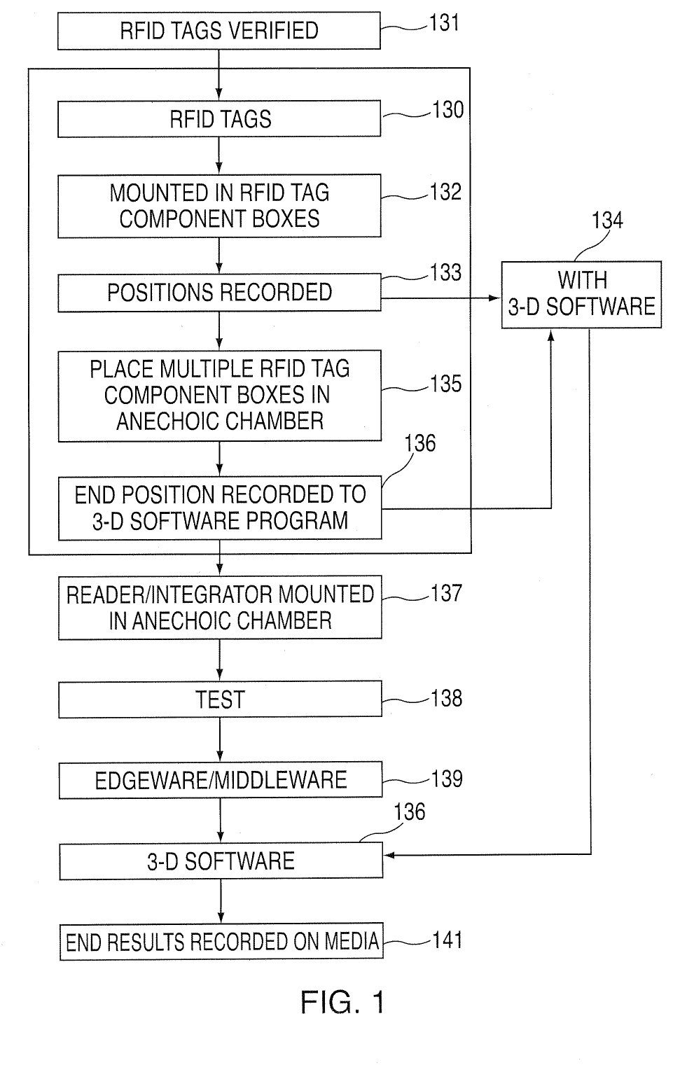

Referring to FIG. 1, the tags 131 are verified prior to use for operability. These tags 130 are mounted in RFID unit boxes 132, and are recorded as a whole unit box with a number of tags and their serialization. This information is provided to the 3-D software data base 134, and placed in an organized systematic manner in an anechoic chamber 135. At this time the end position is recorded 136 in to the 3-D Software 134. The reader/integrator is mounted 137 in the anechoic chamber in front of the RFID tag box units. The reader is turned on and the test is begun. As the test is completed 138 the edgeware or middleware 139 filters out all the duplicate reads, and transfers the filtered data to the 3-D visualizing software 140. The results are recorded in different colors 141 to get a clear 3-D picture of what tie reader sees. This information is then transferred to a permanent media for analysis.

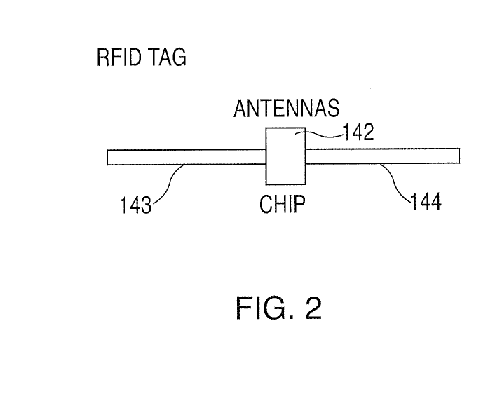

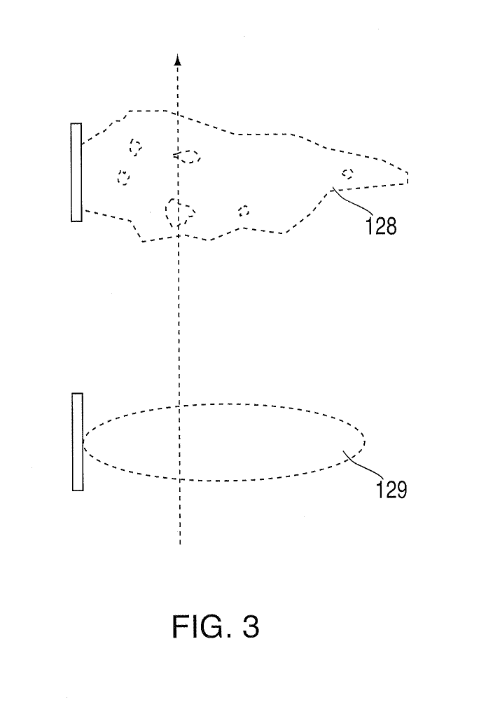

FIG. 2 depicts an RFID generic tag. Items 143 and 144 are antennas for the tag and item 142 is the chip having a serialization number that distinguishes it from other RFID Tabs. FIG. 3 depicts the configuration of a perfect read area 129. It also shows what in reality the read area might look like in and actual implementation.

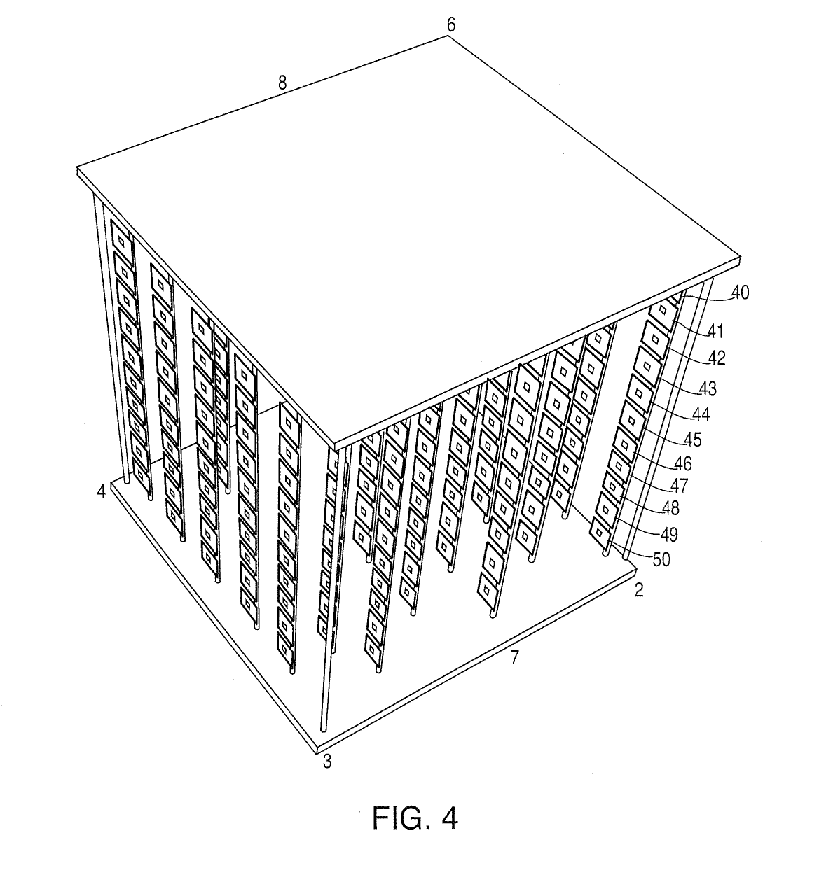

FIG. 4 depicts an RFID tag component enclosure with a top 8 and a bottom 7 and supporting columns 2,3,4,6 that support the components. This is preferably fabricated from carbon based material to avoid interference.

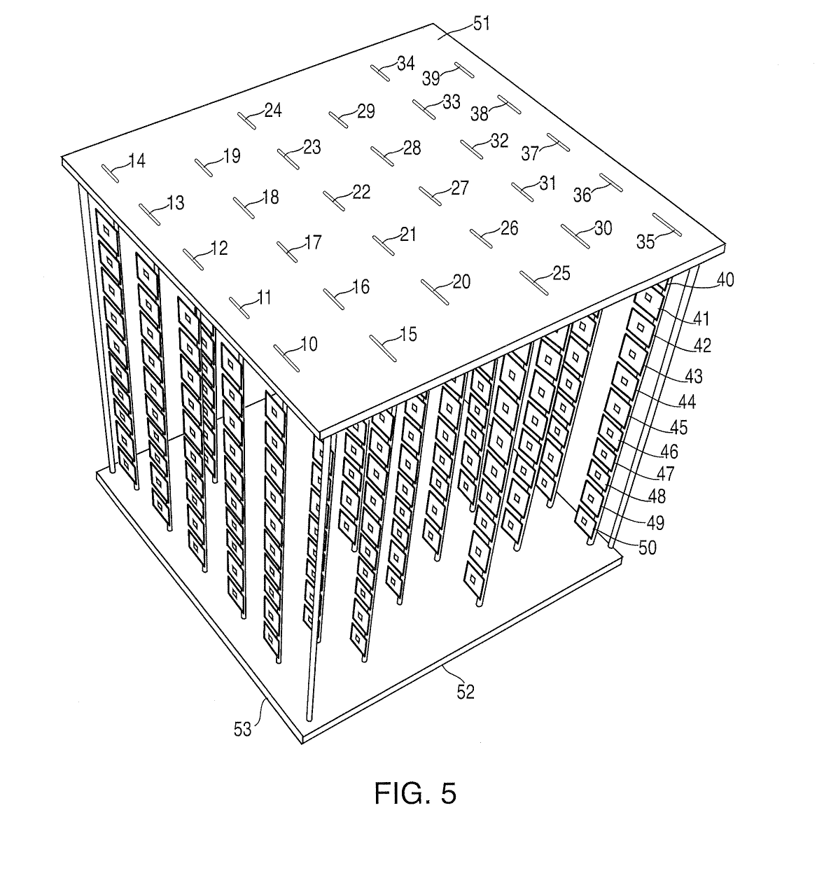

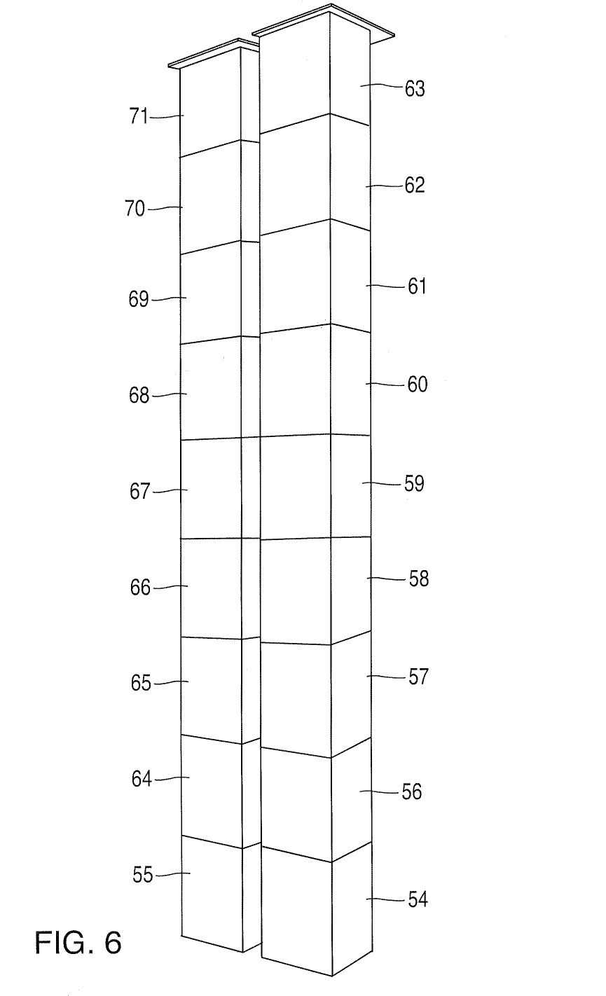

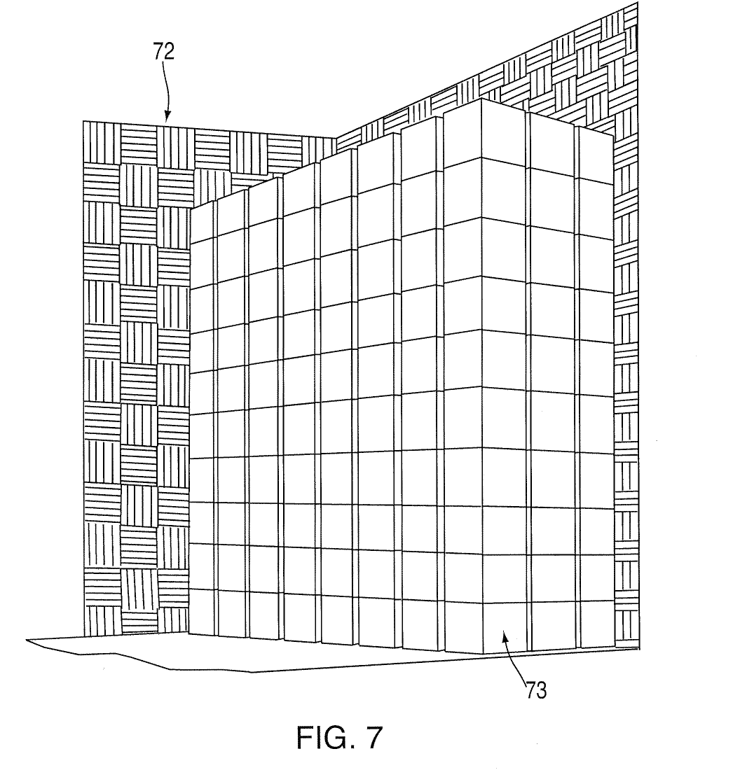

FIG. 5 shows the RFID tags mounted in a line from top to bottom 40 thru 50 and placed n a parallel lines 10 through 14. A second line is placed at right angles 15 thru 19 behind the first line and so on until the enclosure component is full. The horizontal line is secured by inserting a line through the plates of tie RFID component boxes. As shown in FIG. 6, the RFID component boxes 54 thru 71 are placed one on top of the other to form a tower for insertion into an anechoic chamber. FIG. 7 shows several RFID component boxes 73 stacked in place in an anechoic chamber 72.

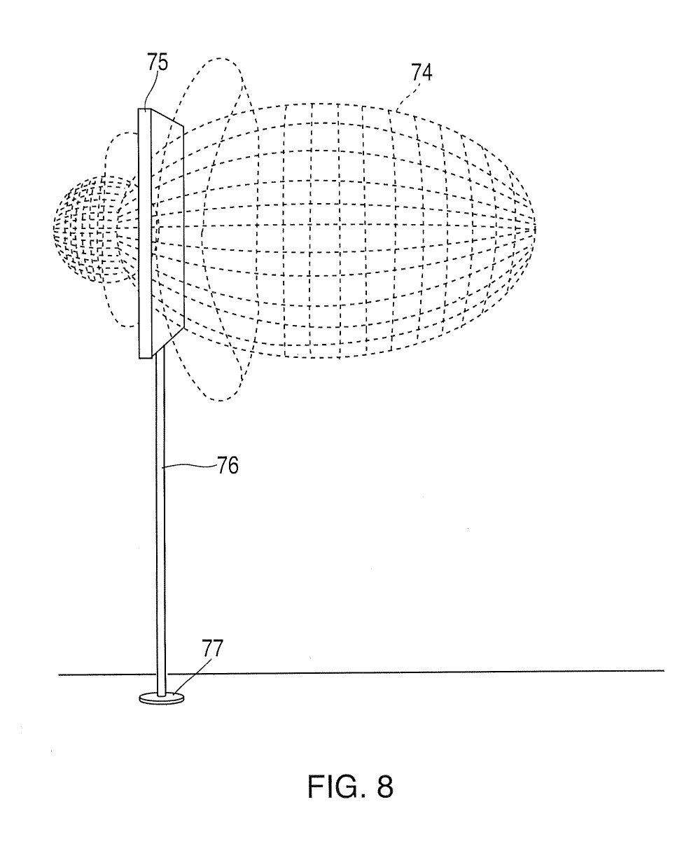

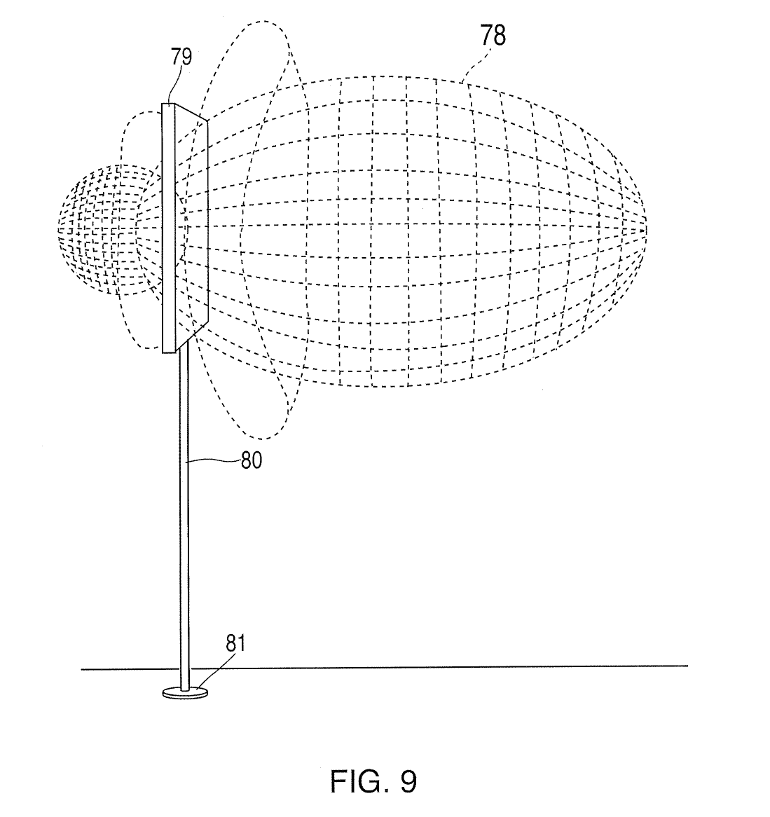

In FIG. 8, a reader 75 is shown mounted on a stand 76 with a base 77. The figure also shows the configuration of a plume 74 when the reader is activated under moderate power. In FIG. 9 a reader 79 is mounted on a stand 80 with a base 81 and the figure shows what a plume 78 looks like as the power is increased above moderate. Note that the plume enlarges as more power is provided until the maximum capacity is achieved.

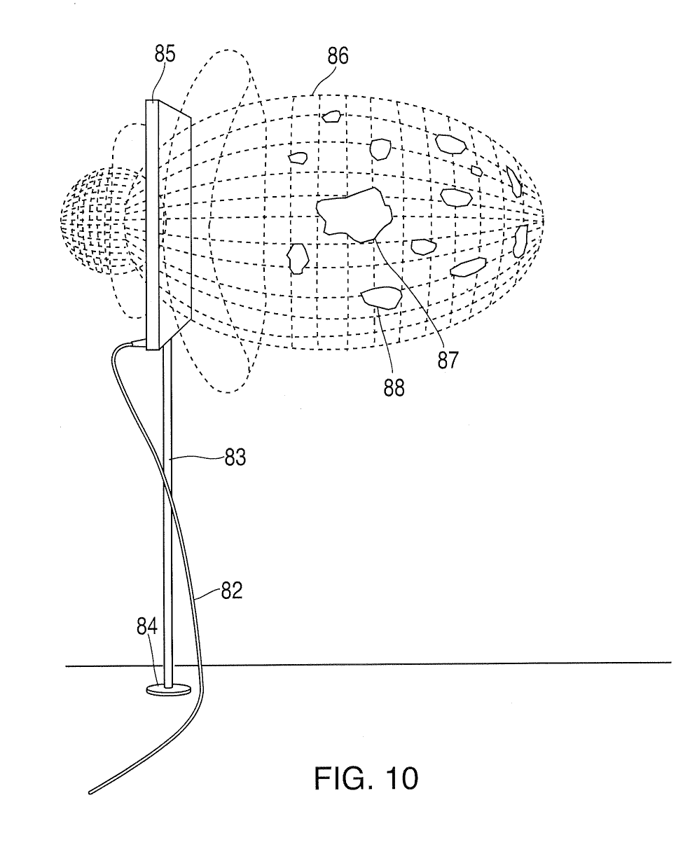

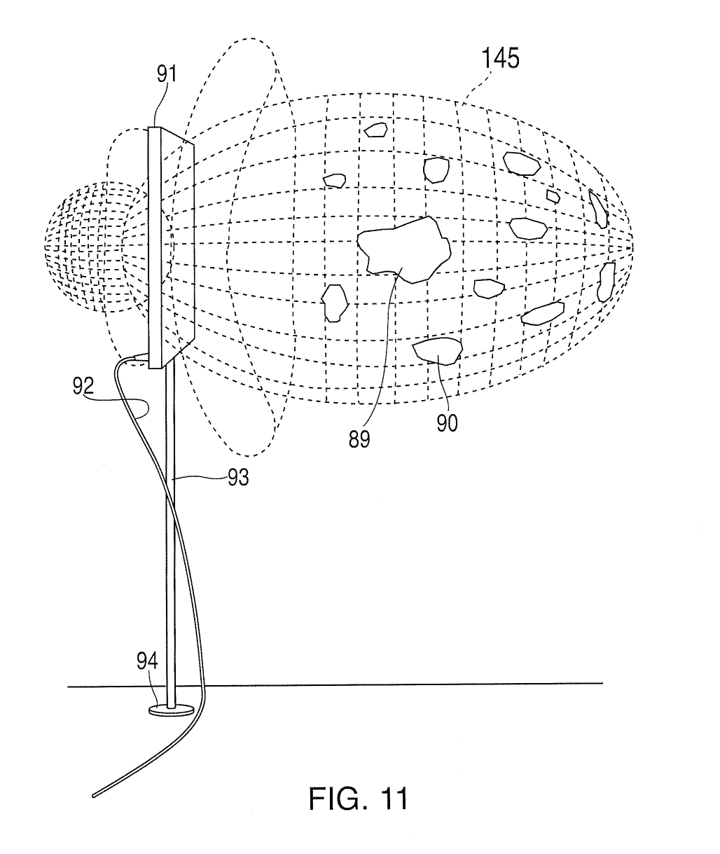

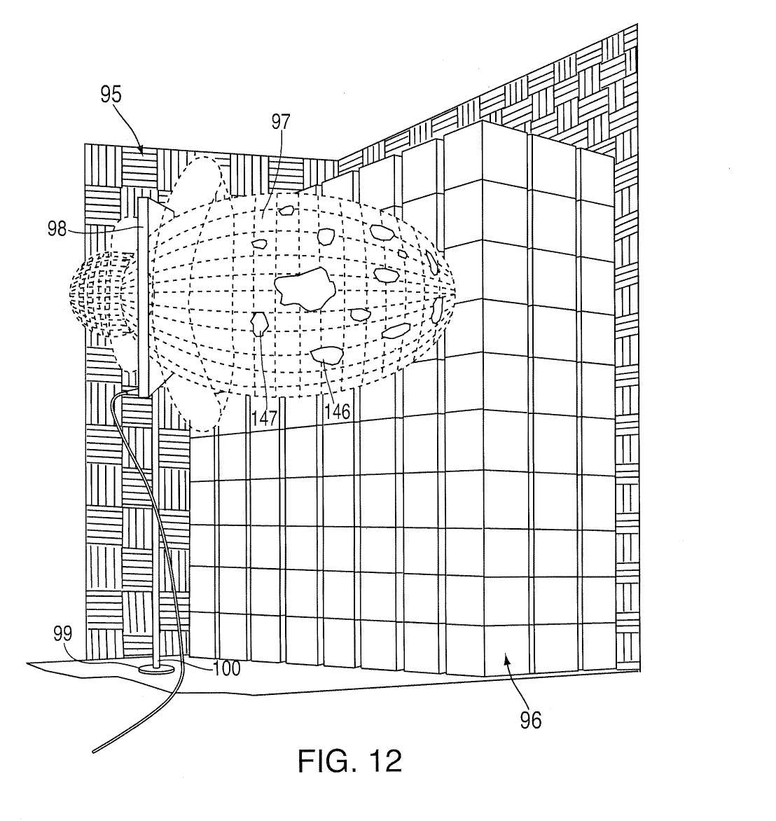

FIG. 10 shows an example in which a reader 85 is mounted on a stand 83 with a base 84 and a cord 82 and a plume 86 with distortions and black holes 87 and 88 at a regular power. In FIG. 11, a reader 91 is mounted on a stand 93 having a base 94 and a cord 92. An enlarged plume 145 compared to the previous figure results from increased power. As show, the distortions and black holes 89 and 90 have increase significantly. In FIG. 12, a reader 98 is mounted on a stand 100 having a base 99 placed in an anechoic chamber 95 facing an array of RFID tag component boxes. A plume 97 is depicted showing the distortions and holes 146 and 147 ready to be tested.

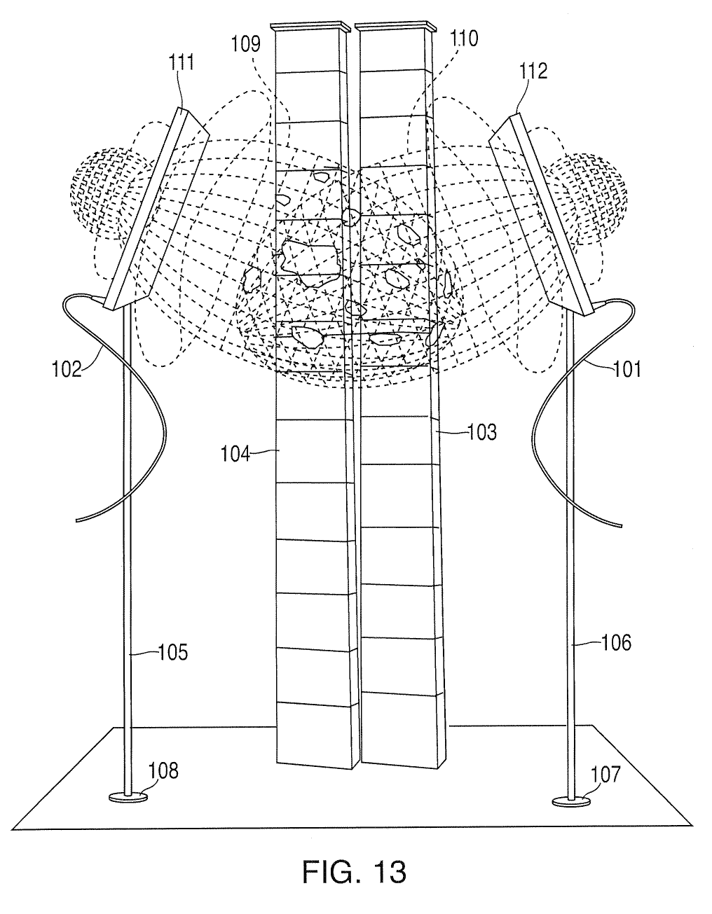

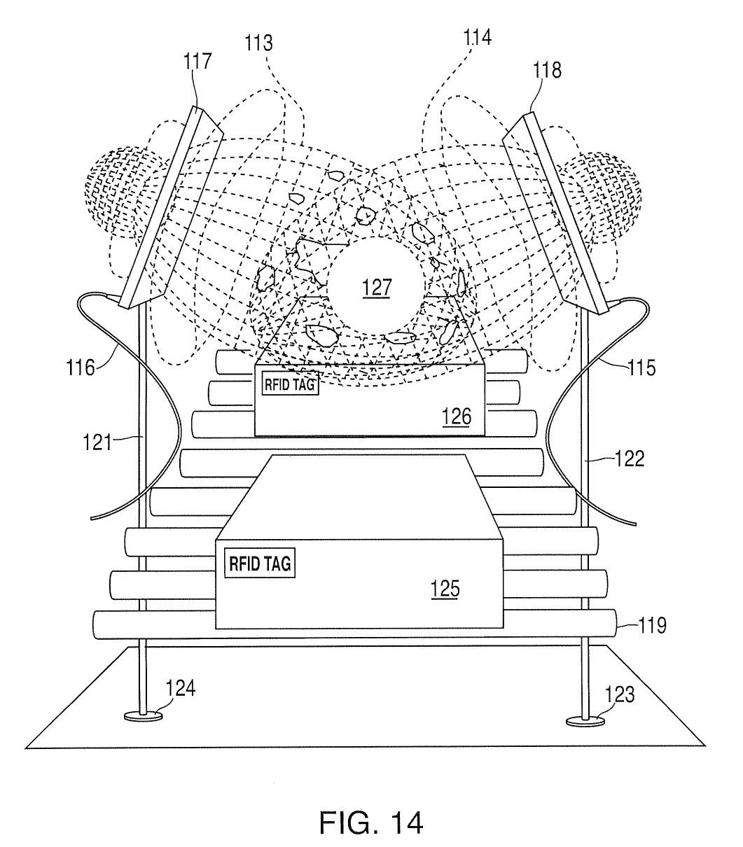

FIG. 13 shows two readers 111 and 112 attached to poles 105 and 106 with bases 107 and 108 and cords 102 and 101 facing two towers of RFID tag component boxes showing plumes 109 and 110. Note that since it is known what their antenna flaws are we can position them at angles so as to have no black holes or distortions in the coverage area. In FIG. 14, two readers 117 and 118 are mounted on stands 122 and 121 with base 124 and 123, and cords 115 and 116. They are powered up to detect tags on an assembly line 119. Shown are two cases 125 and 126 which have RFID tags attached to them. The two plumes are shown as 113 and 114 and are angled with respect to each other to form the sweet spot 127 that is the best read point to enable a 100% read rate.

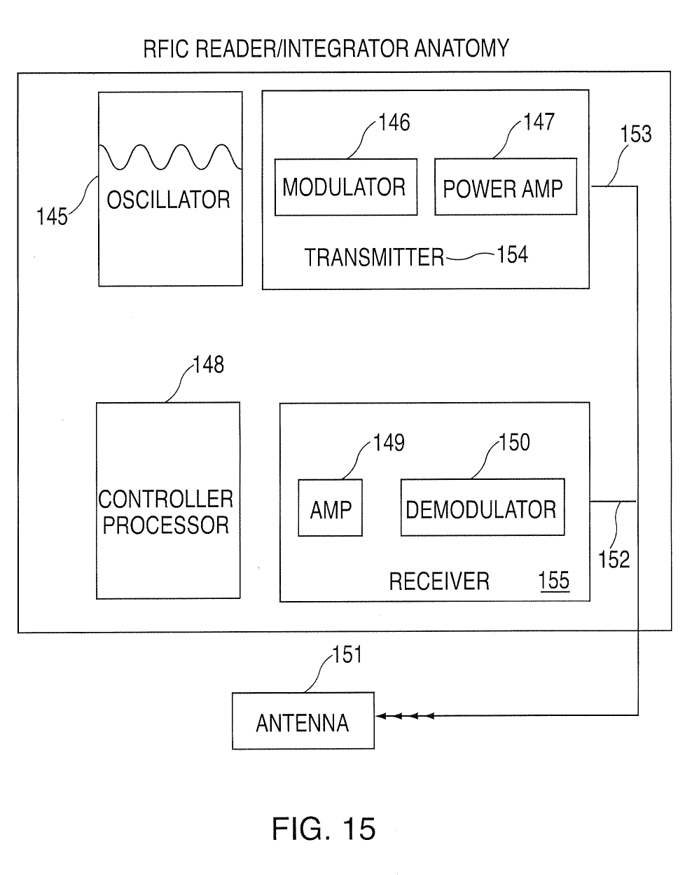

FIG. 15 depicts the basic anatomy of an RFID reader/integrator. The oscillator 145 provides base-band signal to a modulator and reference signal and demodulator circuits. The controller/processor 148 performs data processing and communicates with an external network. The modulator 146 in the transmitter adds information to the base-band signal to be transmitted to the tag. The power amplifier 147 amplifies the modulated signal and routes it to the antenna. The modulator 146 and the power amp 147 are part of the transmitter 154. The amp 149 of the receiver 155 amplifies demodulated signals for processing, and the demodulator 150 of the receiver 155 extracts the information from the signal returning to the tag. 153 and 152 are the input and output ports going to the antenna 151. Note that the antenna 151 is the part that emits the plume signal.

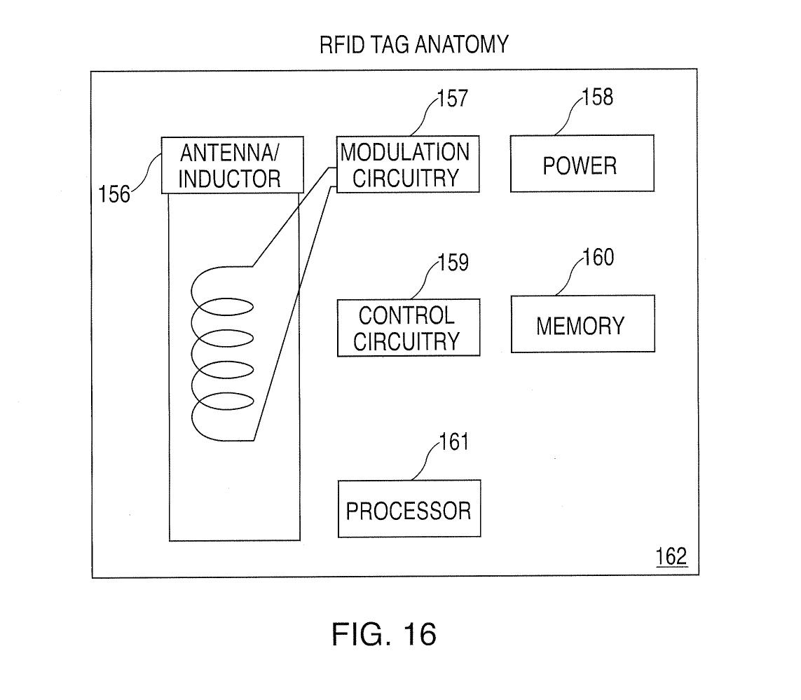

FIG. 16 shows the anatomy of an RFID tag. The power 158 provides electrical power to elements of the tag. The tag can harvest power from a signal received from the reader/integrator or it can have its own battery. The memory 160 would be for a non-writeable and writeable data storage. The processor 161 interprets the signals received from the reader and controls memory storage and retrieval. The control circuitry 159 controls internal functions under the command of the processor. The modulation circuitry 157 adds data to the signal that is transmitted back to the reader. The antenna/inductor 156 senses signals from the RFID reader and also radiates the responses back to the reader.

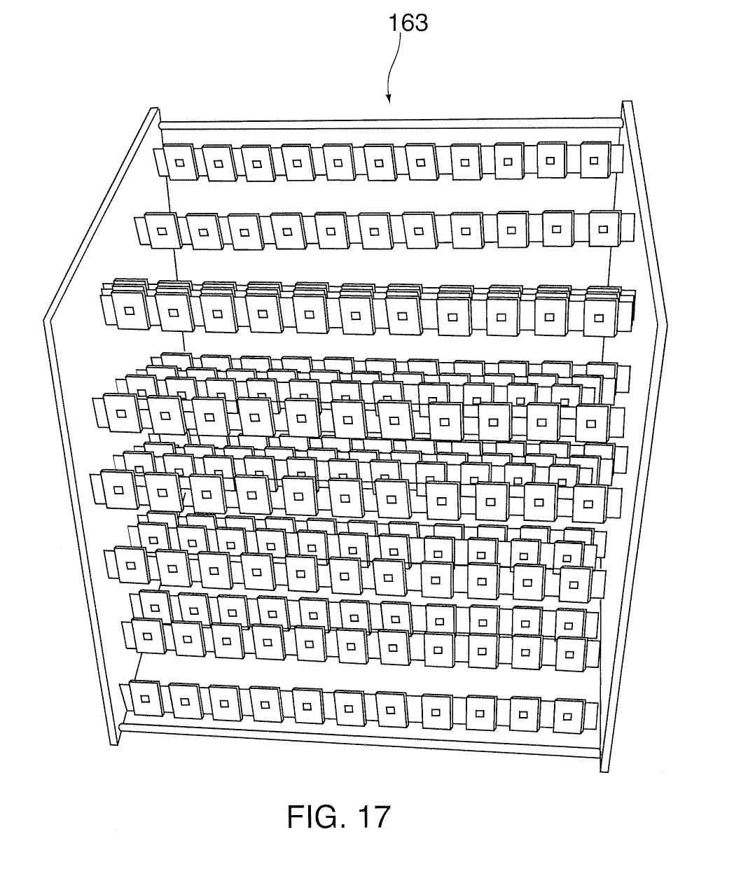

In FIG. 17 the RFID tag component box 163 is shown placed outside of an anechoic chamber in a place that has already implemented RFID systems. It can be used in conjunction with a full Faraday cycle analysis test, or to be able to see what the plume looks like when it is implemented.

The software utilized in conjunction with the invention implements the following method steps.

| Step | | |
|---|---|---|
| No. | Step | Step Description |
| 1 | Create | Initiate a single-pass portal test, whereby |
| | Single-Pass | the testing grid must only traverse along the |
| | Test | antenna axis once, since the beam width is |
| | | sufficiently narrow for the testing grid to |
| | | interact with all of it in one axial traverse. |
| | | This feature will provide controls for the |
| | | user to enter identifying information (a test |
| | | name and/or number, portal identifier, |
| | | antenna identifier, tag manufacturer and |
| | | model number, user name, company name, etc), |
| | | along with the ability to specify |
| | | the manufacturer and model number of the |
| | | interrogator. |
| 2 | Run | Alert the application of the initiation of |
| | Single-Pass | the test. The application will then guide |
| | Test | the user through the steps necessary to |
| | | perform the test and to capture the data. |
| 3 | Display | Choose to display the test results, either |
| | Single-Pass | as a graphical representation of the |
| | Test | antenna's electromagnetic field strength, |
| | Results | or as tabular numeric data. |
| 4 | Save | Choose to save the test results as a |
| | Single-Pass | graphics file in a portable format, or as a |
| | Test | text file of numeric data, or both. The user |
| | Results | may choose to save the data to a file |
| | | either before viewing the data, or after. |
| 5 | Create | Initiate a multi-pass portal test, whereby |
| | Multi-Pass | the testing grid must traverse along each |
| | Test | of four quadrants defined by orthogonal |
| | | axes located in a plane parallel to the |
| | | antenna cover face and normal to the |
| | | antenna axis, since the beam is too wide |
| | | for the testing grid to interact with all |
| | | of it in one axial traverse. |
| | | This feature will provide controls for the |
| | | user to enter identifying information (a |
| | | test name and/or number, portal identifier, |
| | | antenna identifier, tag manufacturer and |
| | | model number, user name, company name, etc), |
| | | along with the ability to specify |
| | | the manufacturer and model number of the |
| | | interrogator. |
| 6 | Run | Alert the application of the initiation of |
| | Multi-Pass | the test. The application will then guide |
| | Test | the user through the steps necessary to |
| | | perform the test and to capture the data. |
| 7 | Display | Choose to display the test results, either |
| | Multi-Pass | as a graphical representation of the |
| | Test | antenna's electromagnetic field strength, |
| | Results | or as tabular numeric data. The data |
| | | collected from each quadrant will be |
| | | combined to produce a single data set |
| | | describing the antenna's |
| | | electromagnetic field. |
| 8 | Save | Choose to save the test results as a |
| | Multi-Pass | graphics file in a portable format, or as |
| | Test | a text file of numeric data, or both. The |
| | Results | user may choose to save the data to a file |
| | | either before viewing the data, or after. |
| 9 | Import | Select a text file containing numeric data |
| | Test Data | generated by the application in a previous |
| | to Display | test and redisplay it graphically. |
| 10 | Re-execute | Choose to re-execute a test, either |
| | a Test | overwriting the previously captured data, |
| | | or saving the new data as another file. |
| | | This feature will re-use the data the |
| | | user entered for the previous test, so that |
| | | it does not have to be re-entered. This |
| | | feature will be available for data imported |
| | | from previously saved text files, as well |
| | | as for data still stored in volatile |
| | | memory from the current test. |

Although the invention has been described in terms of particular embodiments, it will be apparent to persons of skill in this art that certain modifications and use of equivalent equipment will derive the benefit of this invention and are intended to be encompassed within the legal protection afforded by this patent.

What is claimed is:

1. An RFID antenna pattern detector wherein the antenna patterns has holes, comprising
an array of RFID tags arranged in planes,
said array comprising rows and columns of RFID tags having an overlapping arrangement such that the distance between RFID tags is less than a predetermined distance, and the pattern is arranged to intercept a portion of each hole in the planes of the array.

2. The RFID antenna pattern detector of claim 1 in which each row is set back by a predetermined distance from a previous row and shifted laterally by a predetermined amount.

3. The RFID antenna pattern detector of claim 1 in which the array of RFID tags is within an anechoic chamber.

4. The RFID antenna pattern detector of claim 2 in which the array of RFID tags is within an anechoic chamber.

5. The RFID antenna pattern detector of claim 1 in which the tags are of the same class, each providing a reader with signals capable of identifying the tag and its predetermined location in the array.

6. The RFID antenna pattern detector of claim 1 in which the array is one of stack of similar arrays.

7. The RFID antenna patter detector of claim 6, in which the stack fills a volume from floor to ceiling and across the width of a space.

7. The RFID antenna pattern detector of claim 1 in which the detector comprises hinged sections that are collapsible for transport.

8. A method for determining the location of holes in an RFID antenna pattern comprising,
facing an antenna with an array of RFID tags arranged in planes, said array comprising rows and columns of RFID tags having an overlapping arrangement such that the distance between RFID tags is less than a predetermined distance, and the pattern is arranged to intercept a portion of each hole in the planes of the array,
backing away from the antenna until the antenna receives no strong signals from the RFID tags,
advancing the array in increments towards the antenna while recording reading from the tags.
